(19) United States
(12) Patent Application Publication
(10) Pub. No.: US 2014/0077857 A1
(43) Pub. Date: Mar. 20, 2014

(54) CONFIGURABLE DELAY CIRCUIT

(71) Applicants: John W. POULTON, Chapel Hill, NC (US); Robert Palmer, Chapel Hill, NC (US); William James Dally, Los Altos Hills, CA (US)

(72) Inventors: John W. POULTON, Chapel Hill, NC (US); Robert Palmer, Chapel Hill, NC (US); William James Dally, Los Altos Hills, CA (US)

(21) Appl. No.: 13/619,765

(22) Filed: Sep. 14, 2012

(51) Int. Cl. H03H 11/26

(52) U.S. Cl. 327/278

(57) ABSTRACT

One embodiment sets forth a technique for delaying signals by varying amounts. A configurable delay circuit includes fixed and tri-state inverters. Pullup and pulldown transistors within one or more tri-state inverters may be activated to reduce the delay introduced by fixed inverters. The pullup and pulldown transistors within one or more tri-state inverters may be separately activated to independently adjust the rising delay and the falling delay incurred by the input signal.

### BACKGROUND OF THE INVENTION

1. Field of the Invention

The present invention generally relates to a delay circuit and more specifically to a configurable delay circuit.

2. Description of the Related Art

Delay circuits are used to align signals relative to each other, such as aligning a rising and/or falling edge of a clock signal to capture data signals. A conventional circuit that is used to delay a signal includes multiple inverters connected in series, where the output of the last inverter is a delayed version of the input signal. The amount of delay that is incurred may be increased by increasing the number of inverters that are connected in series.

When the amount of delay that is needed is variable, a delay circuit may be used that includes a multiplexer. In such a circuit, the multiplexor receives the outputs of two or more of the different inverters that are connected in series, so that each input to the multiplexor is a different delayed version of the input signal. The multiplexor then selects one of the inputs as the output signal.

While the multiplexor enables the selection of one or more different delays, the multiplexor itself also delays the output signal by an additional amount. The additional delay is referred to as “insertion delay” and is incurred by each delayed version of the input signal. Problematically, the insertion delay may vary from multiplexor to multiplexor due to fabrication process variations, thereby complicating the alignment of signals that are delayed using a given multiplexor.

Accordingly, what is needed in the art is a technique for delaying signals by varying amounts without also incurring insertion delay due to a multiplexor.

### SUMMARY OF THE INVENTION

One embodiment of the present invention sets forth a technique for delaying signals by varying amounts. A configurable delay circuit includes fixed and tri-state inverters. Pullup and pulldown transistors within one or more tri-state inverters may be activated to reduce the delay introduced by fixed inverters. The pullup and pulldown transistors within one or more tri-state inverters may be separately activated to independently adjust the rising delay and the falling delay incurred by the input signal.

Various embodiments of the invention comprise a configurable delay circuit that includes a fixed inverter element coupled in parallel with a tri-state inverter element. The fixed inverter element is configured to receive an input signal and generate an inverted input signal that is delayed relative to the input signal by a first amount of time. The tri-state inverter element is configured to receive the input signal and reduce the first amount of time that the inverted input signal is delayed relative to the input signal when at least one of a first control signal and second control signal is activated.

Various embodiments of the invention for generating an output signal that is delayed relative to an input signal include receiving a first control signal that controls a first delay of a rising edge of the output signal relative to a rising edge of the input signal and receiving a second control signal that controls a second delay of a falling edge of the output signal relative to a falling edge of the input signal. The first control signal and the second control signal are applied to a configurable delay circuit that receives the input signal and generates the output signal such that the output signal is delayed by the first delay and the second delay relative to the input signal.

One advantage of the disclosed mechanism is that the configurable delay circuit delays signals by varying amounts without incurring an additional insertion delay from a multiplexor.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A illustrates a configurable delay circuit, according to one embodiment of the present disclosure;

FIG. 1B illustrates a stage of the configurable delay circuit of FIG. 1A, according to one embodiment of the present disclosure;

FIG. 1C, illustrates a delay transfer characteristic of the configurable delay circuit of FIG. 1A, according to one embodiment of the present disclosure;

FIG. 2 is a flowchart illustrating a technique for configuring the configurable delay circuit, according to one embodiment of the present disclosure;

FIG. 3A is a block diagram illustrating a processor/chip including the configurable delay circuit of FIG. 1A, in accordance with one or more aspects of the present disclosure; and

FIG. 3B is a block diagram illustrating a computer system configured to implement one or more aspects of the present invention.

### DETAILED DESCRIPTION

In the following description, numerous specific details are set forth to provide a more thorough understanding of the present invention. However, it will be apparent to one of skill in the art that the present invention may be practiced without one or more of these specific details. In other instances, well-known features have not been described in order to avoid obscuring the present invention.

A configurable delay circuit can be used to correct mismatches in delays between signals such as between clock signals and data and between different bits of data within a multi-bit data bus. Misaligned clock edges relative to data signals can result in functional errors, e.g., timing errors. The configurable delay circuit may be used to align the clock relative to the data signals and ensure that timing requirements are better met.

Mismatches in delays between different signals of a multi-bit data bus present challenges for meeting the timing requirements to correctly sample all signals of the multi-bit data bus. The mismatches are typically caused by varying wire lengths and variations due to the silicon fabrication process for the different data signals of the multi-bit data bus. In particular, the delays of different repeater elements that are inserted along the length of data and clock signal wires may vary, resulting in mismatches between the different data signals and between clock signals relative to the data signals. The configurable delay circuit may be used to minimize the variation between the valid sampling windows for each data signal of a multi-bit bus, thereby reducing functional errors.

Other potential sources of systematic skew between clock and data signals are asymmetry in the clock buffers at the transmitter and receiver ends of a link over which the data is transmitted, and aperture offsets in the receiver flip-flops. Adjustments of the forwarded clock phase can be made using the configurable delay circuit to compensate for such offsets. The ability to independently adjust the rising delay and falling delay provided by the configurable delay circuit allows for trimming of the data signals and for adjustment of a clock signal duty-cycle or pulse-width. Adjustment of the rising-edge timing should be essentially independent of the falling-edge timing. Otherwise, if the adjustments to each edge interact strongly, it is difficult to find a suitable tuning algorithm for removing timing offsets.

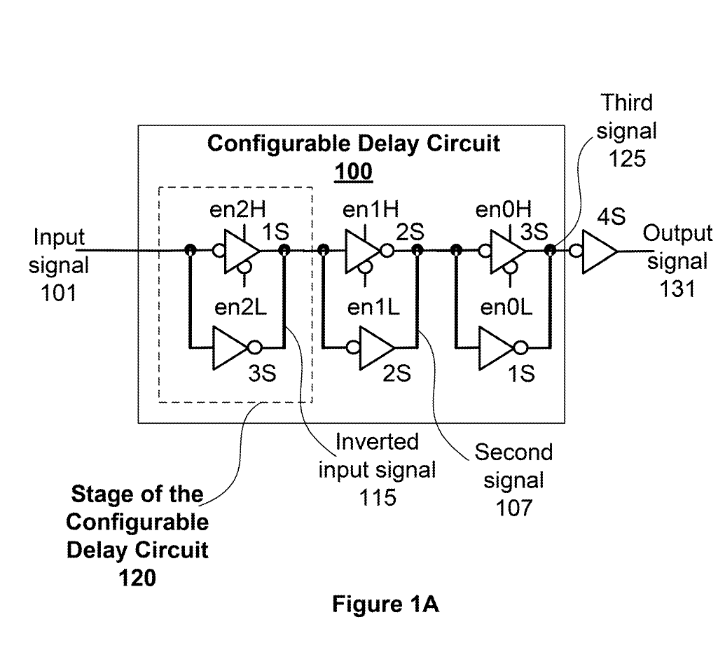

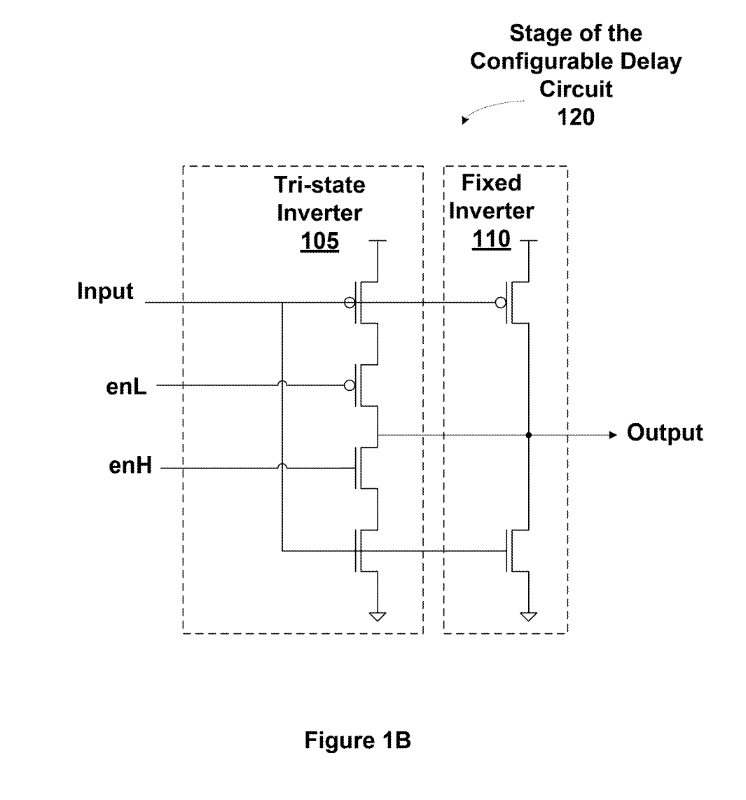

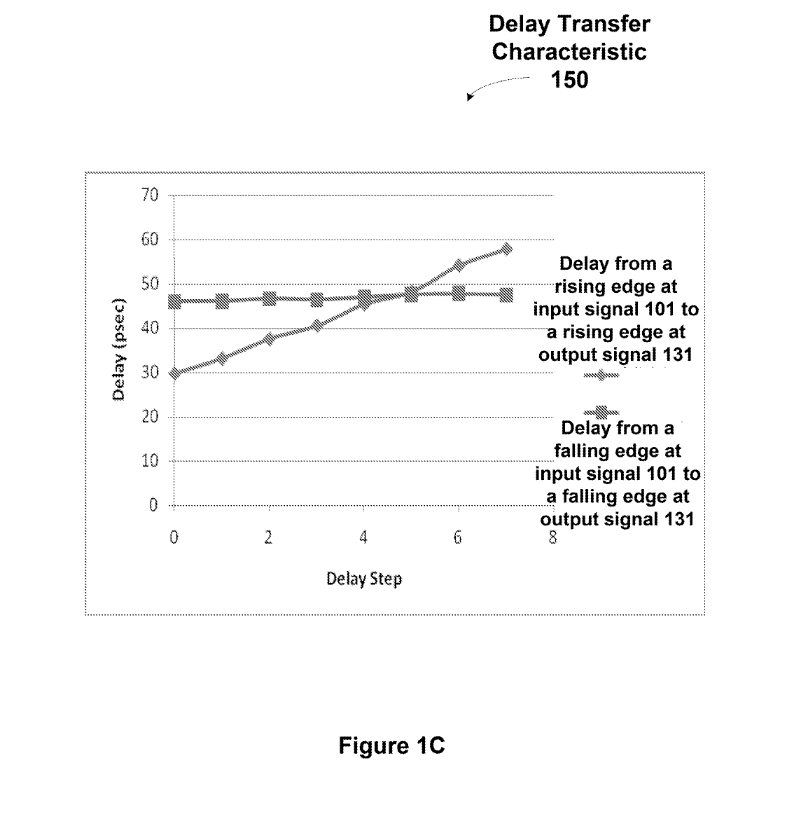

FIG. 1A illustrates a configurable delay circuit 100, according to one embodiment of the present disclosure. As shown in FIG. 1A, the configurable delay circuit 100 includes three adjustable stages, where each stage (e.g., stage of the configurable delay circuit 100) comprises a fixed inverter coupled in parallel with a tri-state inverter. Other configurable delay circuits may include one or more adjustable stages to generate an output signal that is delayed relative to an input signal based on at least two independent control signals. The configurable delay circuit 100 receives an input signal 101 and generates an output signal 131 that is delayed relative to the input signal 101 based on control signals en2H, en1H, en0H, en2L, en1L, and en0L.

At each stage of the configurable delay circuit 100, the rising edge at the output of a particular stage can be delayed by de-asserting the respective control signal en2L, en1L, and en0L for the particular stage. The falling edge at the output of a particular stage can be delayed by de-asserting the respective control signal en2H, en1H, and en0H for the particular stage. By assembling a series of these stages of the configurable delay circuit 100, a range of control for the timing of each output edge may be achieved. For example, the rising-edge timing at the output signal 131 is controlled by the set of controls en2H, en1L, and en0H. The falling-edge timing at the output signal 131 is controlled by the remaining three controls, e.g., controls en2L, en1H, and en0L. The structure of multiple stages provides a very flexible mechanism for controlling the relative delay between the output and input of each stage and the overall delay of the output signal 131 relative to the input signal 101, because the overall sizing of each stage and the relative sizes of the fixed and adjustable tri-state inverters are free parameters.

FIG. 1B illustrates a stage of the configurable delay circuit 100 that is one of the three stages shown in the configurable delay circuit 100 of FIG. 1A, according to one embodiment of the present disclosure. The stage of the configurable delay circuit 100 comprises a tri-state inverter 105 coupled in parallel with a fixed inverter 110. The tri-state inverter 105 and the fixed inverter 110 each receive the input and generate an output that is an inverted version of the input.

The enL control signal enables and disables the pull-up transistor of the tri-state inverter 105. When the active-low enL control signal is asserted (i.e., driven low), the pull-up operation of the tri-state inverter 105 is enabled. When the active-high enH control signal is asserted (i.e., driven high), the pull-down operation of the tri-state inverter 105 is enabled. When neither enL nor enH is asserted the output of the tri-state inverter 105 is in a high impedance state and the output is driven only by the fixed inverter 110.

The fixed inverter 110 provides a first level of drive strength to drive a load at the output. When enL is asserted, the drive strength of a rising transition at the output is greater due to the tri-state inverter 105 pull-up, so the delay of the rising transition is reduced. Similarly, when enH is asserted the drive strength of a falling transition at the output is greater due to the tri-state inverter 105 pull-down, so the delay of the falling transition is reduced. Assuming that the logical effort, a measure of drive strength, for a fixed inverter 110 is 1, the logical effort of the tri-state inverter 105 is 2 when all transistors are equally sized. Therefore, the drive strength of the stage of the configurable delay circuit 100 is increased by 50% with the tri-state inverter 105 is enabled.

The relative drive strength of each stage is determined based on the widths of the transistors comprising the tri-state inverter 105 and the fixed inverter 110. Each stage of the configurable delay circuit 100 can be configured to provide four different delay variations using the control signals enL and enH. A first delay is incurred by the input to generate the output when enL and enH are both de-asserted. The first delay is reduced for the rising edge of the output and the falling edge of the output when enL and enH are both asserted to increase the drive strength of the state of the configurable delay circuit 100. The first delay is reduced only for the rising edge of the output when enL is asserted and enH is de-asserted. Finally, the first delay is reduced only for the falling edge of the output when enH is asserted and enL is de-asserted.

The relative sizing of the transistors comprising the tri-state inverter 105 and the fixed inverter 110 may be used to control the possible delays and reduced delays that are generated by each stage of the configurable delay circuit 100. For example, assuming that each stage in the configurable delay circuit 100 shown in FIG. 1A has a fixed overall sizing (or drive strength) of 4S, there are 3 different possible combinations of relative sizing between the transistors of the tri-state inverter 105 and the transistors of the fixed inverter 110. The fixed inverter 110 may have a size of 3S and the tri-state inverter 105 may have a size of 1S. The fixed inverter 110 may have a size of 2S and the tri-state inverter 105 may have a size of 2S. The fixed inverter 110 may have a size of 1S and the tri-state inverter 105 may have a size of 3S. Each stage of the configurable delay circuit 100 presents a load of 4S to the previous stage (or the input).

FIG. 1C, illustrates a delay transfer characteristic 150 of the configurable delay circuit of FIG. 1A, according to one embodiment of the present disclosure. As shown in FIG. 1C, the rising edge of the input signal 101 is delayed by varying amounts to generate the rising edge of output signal 131. When en2H is asserted, the pull-down device within the tri-state inverter element in the first stage of the configurable delay circuit 100 is activated to reduce the delay of the transition from the rising edge of the input signal 101 to the falling edge of the inverted input signal 115. When en1L is asserted, the pull-up device within the tri-state inverter element in the second stage of the configurable delay circuit 100 is activated to reduce the delay of the transition from the falling edge of the inverted input signal 115 to the rising edge of the second signal 107. When en0H is asserted, the pull-down device within the tri-state inverter element in the third stage of the configurable delay circuit 100 is activated to reduce the delay of the transition from the rising edge of the second signal 107 to the falling edge of the third signal 125. The output signal 131 is the inversion of the third signal 125, so the falling edge on the third signal 125 produces a rising edge at the output 131.

The delay transfer characteristic 150 corresponds to a configurable delay circuit 100 where the first stage has a tri-state inverter of size 1S and a fixed inverter of size 3S, the second stage has a tri-state inverter of size 2S and a fixed inverter of size 2S, and the third stage has a tri-state inverter of size 3S and a fixed inverter of size 1S.

The lowest delay of approximately 30 picoseconds occurs when the en2H, en1L, and en0H control signals are asserted so that the respective pull-down devices and pull-up device in the tri-state inverter elements are activated. The largest delay of approximately 58 picoseconds occurs when the en2H, en1L, and en0H control signals are un-asserted so that the respective pull-down devices and pull-up device in the tri-state inverter elements that are controlled by the en2H, en1L, and en0H control signals are deactivated.

The rising edge of the input signal 101 is delayed by an increasing amount of time as the en2H, en1L, and en0H control signals progress through the following eight different binary values that each correspond to a different delay step:

101, 100, 111, 110, 001, 000, 011, 010, where the minimum delay is specified by 101 and the maximum delay is specified by 010 because en1L is active low. While adjustments in the en2H, en1L, and en0H control signals affect the delay generated on the rising edge of the output signal 131, the adjustments to the en2H, en1L, and en0H control signals do not affect the delay of the falling edge of the output signal 131. As shown in FIG. 1C, the delays introduced during a rising edge transition of the output signal 131 vary linearly based on at least one of the en2H, en1L, and en0H control signals.

The following table represents the different drive strengths of the stages controlled as en2H, en1L, and en0H are adjusted to progressively decrease the delay of the rising edge at the output 131.

| | First stage | Second stage | Third stage |
|---|---|---|---|
| En2H, en1L, en0H | drive strength | drive strength | drive strength |
| 010 | 3 | 2 | 1 |
| 110 | 3½ | 2 | 1 |
| 000 | 3 | 3 | 1 |
| 100 | 3½ | 3 | 1 |
| 011 | 3 | 2 | 2½ |
| 111 | 3½ | 2 | 2½ |
| 001 | 3 | 3 | 2½ |
| 101 | 3½ | 3 | 2½ |

As shown in FIG. 1C, the delay of the falling edge of the output signal 131 remains substantially constant while the en2H, en1L, and en0H control signals vary and the en2L, en1H, and en0L control signals are not adjusted, i.e., are held constant. Similarly, the delay of the rising edge of the output signal 131 remains substantially constant while the en2L, en1H, and en0L control signals vary and the en2H, en1L, and en0H control signals are not adjusted. Also, the delays introduced during a rising edge transition of the output signal 131 vary linearly based on at least one of the en2L, en1H, and en0L control signals.

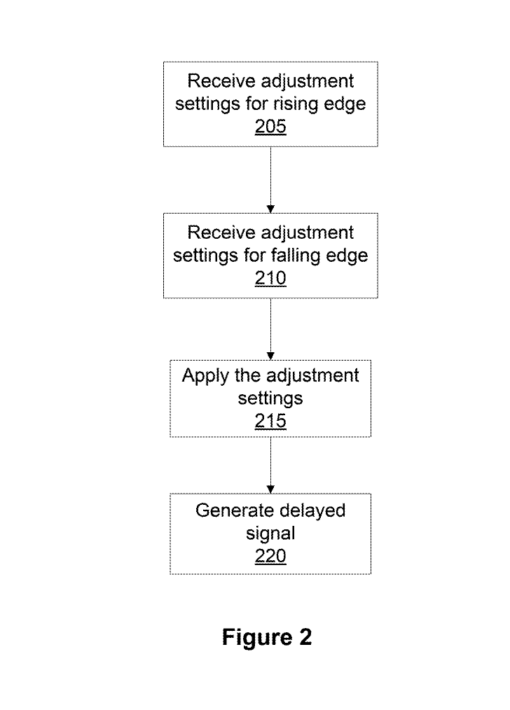

FIG. 2 is a flowchart illustrating a technique for configuring the configurable delay circuit 100, according to one embodiment of the present disclosure. Although the method steps are described in conjunction with the configurable delay circuit 100 of FIG. 1A, persons of ordinary skill in the art will understand that any system configured to perform the method steps, in any order, is within the scope of the disclosure. At step 205 control signal settings are received that control a delay incurred by the rising edge of the input signal 101 to generate the output signal 131. In other words, the control signal settings control the delay of the rising edge of the output signal 131 relative to the rising edge of the input signal 101. The control signal settings that control a delay of the rising edge are en2H, en1L, and en0H

At step 210 control signal settings are received that control a delay incurred by the falling edge of the input signal 101 to generate the output signal 131. In other words, the control signal settings control the delay of the falling edge of the output signal 131 relative to the falling edge of the input signal 101. The control signal settings that control a delay of the falling edge are en2L, en1H, and en0L. At step 215 the control signal settings are applied to the configurable delay circuit 100 to control the amount of delay incurred by the input signal to generate the output signal. At step 220, the output signal that is delayed relative to the input signal is generated.

The control signals of the configurable delay circuit 100 may be adjusted to independently increase or decrease the delay of a rising transition at the output separately from a falling transition at the output. The configurable delay circuit 100 may be adjusted via the control signals to reduce the delay variation between different signals of a multi-bit bus for rising and/or falling data transitions. A predetermined acceptable delay variation may be identified. The predetermined acceptable delay variation may be identified to improve the functional yield of an integrated circuit for a particular performance level, e.g., clock rate. In one embodiment, the relative drive strengths of the fixed inverter and the tri-state inverter are implemented in the configurable delay circuit 100 so that one or more delay steps equals the predetermined acceptable delay variation.

### System Overview

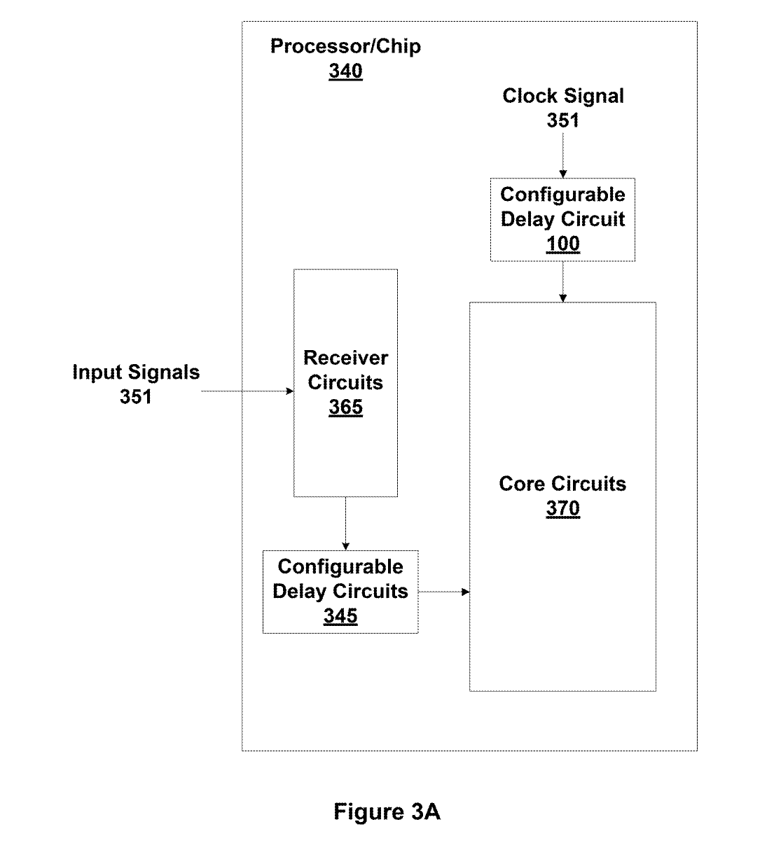

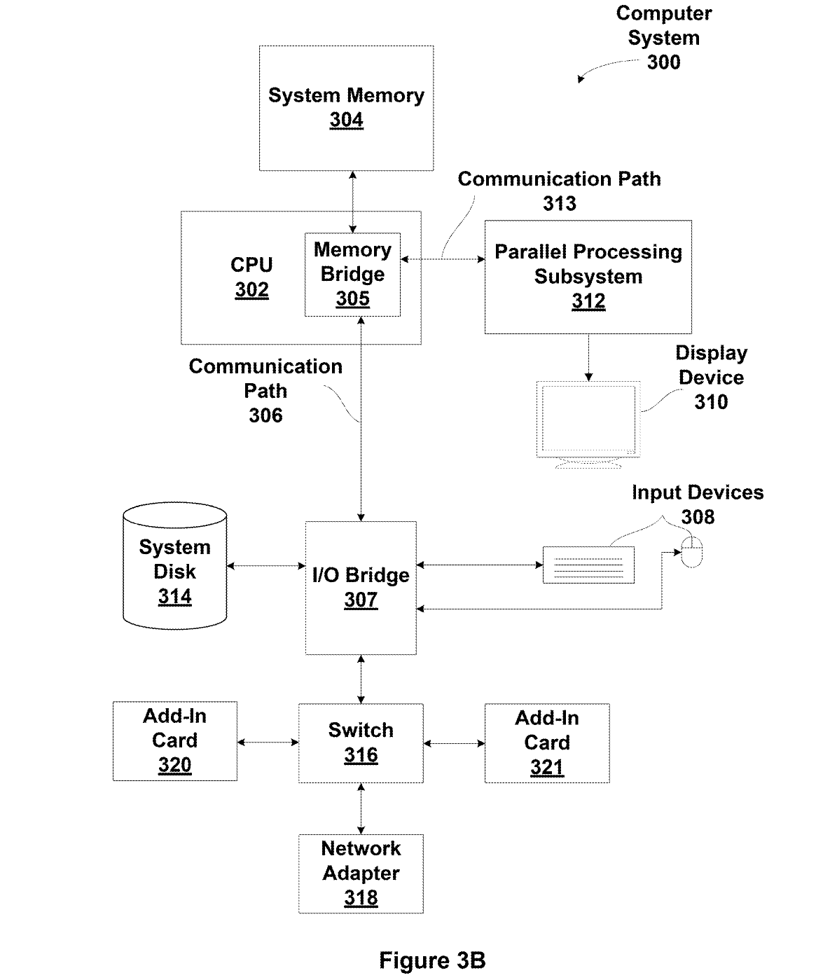

FIG. 3A is a block diagram illustrating a processor/chip 340 including a configurable delay circuit, such as the configurable delay circuit 100 FIG. 1A, in accordance with one or more aspects of the present disclosure. Receiver circuits 365 may include receivers configured to receive input signals from other devices in a system. The receiver circuits 365 provide inputs to the core circuits 370 via the configurable delay circuits 345 that include one or more configurable delay circuits 100. The core circuits 370 may be configured to process the delayed input signals and generate outputs (not shown). The core circuits 370 may also be configured to receive a clock signal 351 via a configurable delay circuit 100. The configurable delay circuit 100 is configured using the control signals to delay the clock signal 351 as needed by the core circuits.

FIG. 3B is a block diagram illustrating a computer system 300 configured to implement one or more aspects of the present invention. Computer system 300 includes a central processing unit (CPU) 302 and a system memory 304 communicating via an interconnection path that may include a memory bridge 305. Memory bridge 305, which may be, e.g., a Northbridge chip, is connected via a bus or other communication path 306 (e.g., a HyperTransport link) to an I/O (input/output) bridge 307. One or more of the devices shown in FIG. 3B may include the configurable delay circuit 100 to delay clock and/or data signals.

I/O bridge 307, which may be, e.g., a Southbridge chip, receives user input from one or more user input devices 308 (e.g., keyboard, mouse) and forwards the input to CPU 302 via communication path 306 and memory bridge 305. A parallel processing subsystem 312 is coupled to memory bridge 305 via a bus or second communication path 313 (e.g., a Peripheral Component Interconnect (PCI) Express, Accelerated Graphics Port, or HyperTransport link); in one embodiment parallel processing subsystem 312 is a graphics subsystem that delivers pixels to a display device 310 (e.g., a conventional cathode ray tube or liquid crystal display based monitor). A system disk 314 is also connected to I/O bridge 307. A switch 316 provides connections between I/O bridge 307 and other components such as a network adapter 318 and various add-in cards 320 and 321. Other components (not explicitly shown), including universal serial bus (USB) or other port connections, compact disc (CD) drives, digital video disc (DVD) drives, film recording devices, and the like, may also be connected to I/O bridge 307. The various communication paths shown in FIG. 3B, including the specifically named communication paths 306 and 313 may be implemented using any suitable protocols, such as PCI Express, AGP (Accelerated Graphics Port), HyperTransport, or any other bus or point-to-point communication protocol(s), and connections between different devices may use different protocols as is known in the art.

In one embodiment, the parallel processing subsystem 312 incorporates circuitry optimized for graphics and video processing, including, for example, video output circuitry, and constitutes a graphics processing unit (GPU). In another embodiment, the parallel processing subsystem 312 incorporates circuitry optimized for general purpose processing, while preserving the underlying computational architecture, described in greater detail herein. In yet another embodiment, the parallel processing subsystem 312 may be integrated with one or more other system elements in a single subsystem, such as joining the memory bridge 305, CPU 302, and I/O bridge 307 to form a system on chip (SoC).

It will be appreciated that the system shown herein is illustrative and that variations and modifications are possible. The connection topology, including the number and arrangement of bridges, the number of CPUs 302, and the number of parallel processing subsystems 312, may be modified as desired. For instance, in some embodiments, system memory 304 is connected to CPU 302 directly rather than through a bridge, and other devices communicate with system memory 304 via memory bridge 305 and CPU 302. In other alternative topologies, parallel processing subsystem 312 is connected to I/O bridge 307 or directly to CPU 302, rather than to memory bridge 305. In still other embodiments, I/O bridge 307 and memory bridge 305 might be integrated into a single chip instead of existing as one or more discrete devices. Large embodiments may include two or more CPUs 302 and two or more parallel processing systems 312. The particular components shown herein are optional; for instance, any number of add-in cards or peripheral devices might be supported. In some embodiments, switch 316 is eliminated, and network adapter 318 and add-in cards 320, 321 connect directly to I/O bridge 307.

In sum, the configurable delay circuit includes tri-state inverters that are coupled in parallel with fixed inverters and that are selectively activated to reduce the delay introduced into the input signal by the fixed inverters. The pullup and pulldown transistors within one or more tri-state inverters may be separately activated to independently adjust the rising edge delay and the falling edge delay incurred by the input signal. When the configurable delay circuit is implemented with three stages of tri-state and fixed inverter pairs, the transistors may be sized such that the different delays incurred by the rising and/or falling edges of the input signal vary linearly.

Advantageously, the configurable delay circuit delays signals by varying amounts without incurring an additional insertion delay. In particular, the adjustment to the delay for either the rising or the falling edge does not interact with the delay incurred by the opposing edge. Therefore, the rising and falling edges may be independently adjusted to control a clock duty factor or a pulse width.

One embodiment of the invention may be implemented as a program product for use with a computer system. The program(s) of the program product define functions of the embodiments (including the methods described herein) and can be contained on a variety of computer-readable storage media. Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored.

The invention has been described above with reference to specific embodiments. Persons skilled in the art, however, will understand that various modifications and changes may be made thereto without departing from the broader spirit and scope of the invention as set forth in the appended claims. The foregoing description and drawings are, accordingly, to be regarded in an illustrative rather than a restrictive sense.

Therefore, the scope of embodiments of the present invention is set forth in the claims that follow.

1. A configurable delay circuit, comprising:
a fixed inverter element configured to receive an input signal and generate an inverted input signal that is delayed relative to the input signal by a first amount of time; and
a tri-state inverter element that is coupled in parallel with the fixed inverter element and is configured to receive the input signal and reduce the first amount of time that the inverted input signal is delayed relative to the input signal when at least one of a first control signal and second control signal is activated, wherein the tri-state inverter element comprises a pull-up transistor that is activated by the first control signal and a pull-down transistor that is activated by the second control signal.

2. The configurable delay circuit of claim 1, further comprising:
a second fixed inverter element that is coupled to the fixed inverter circuit element and configured to receive the inverted input signal and generate a second signal, wherein the second signal is delayed relative to the inverted input signal by a second amount of time; and
a second tri-state inverter element that is coupled in parallel with the second fixed inverter element and is configured to receive the inverted input signal and reduce the second amount of time that the second signal is delayed relative to the inverted input signal when at least one of a third control signal and fourth control signal is activated.

3. The configurable delay circuit of claim 2, further comprising:
a third fixed inverter element that is coupled to the second fixed inverter circuit element and configured to receive the second signal and generate an output signal that is delayed relative to the second signal by a third amount of time; and
a third tri-state inverter element that is coupled in parallel with the third fixed inverter circuit element and is configured to receive the second signal and reduce the third amount of time that the output signal is delayed relative to the second signal when at least one of a fifth control signal and sixth control signal is activated.

4. The configurable delay circuit of claim 1, wherein the first control signal delays a rising edge of the output signal.

5. The configurable delay circuit of claim 1, wherein the second control signal delays a falling edge of the output signal.

6. The configurable delay circuit of claim 1, wherein the first amount of time equals a width of a predetermined acceptable delay variation between different data signals.

7. The configurable delay circuit of claim 1, wherein the input signal and the inverted input signal comprise clock signals.

8. The configurable delay circuit of claim 1, wherein the wherein the input signal and the inverted input signal comprise data signals.

9. The configurable delay circuit of claim 1, wherein a drive strength of the tri-state inverter element is less than a drive strength of the fixed inverter circuit element.

10. The configurable delay circuit of claim 1, wherein a drive strength of the tri-state inverter element is greater than a drive strength of the fixed inverter circuit element.

11. The configurable delay circuit of claim 2, wherein the first amount of time, the second amount of time, the reduced first amount of time, and the reduced second amount of time vary linearly based on at least one of the first control signal the second control signal, the third control signal, and the fourth control signal.

12. A method for generating an output signal that is delayed relative to an input signal, the method comprising:
receiving, at a tri-state inverter element, a first control signal that controls a first delay of a rising edge of the output signal produced by the tri-state inverter element relative to a rising edge of the input signal received by the tri-state inverter element;
receiving, at the tri-state inverter element, a second control signal that controls a second delay of a falling edge of the output signal produced by the tri-state inverter element relative to a falling edge of the input signal received by the tri-state inverter element; and
applying the first control signal and the second control signal to a configurable delay circuit that receives the input signal and generates the output signal such that the output signal is delayed by the first delay and the second delay relative to the input signal.

13. The method of claim 12, wherein at least one of the first delay and the second delay equals a width of a predetermined acceptable delay variation between different data signals.

14. The method of claim 12, wherein the input signal and the output signal comprise clock signals.

15. The method of claim 12, wherein the input signal and the output signal comprise data signals.

16. The method of claim 12, wherein a drive strength of the tri-state inverter element within the configurable delay circuit is less than a drive strength of a fixed inverter element within the configurable delay circuit.

17. The method of claim 12, wherein a drive strength of the tri-state inverter element within the configurable delay circuit is greater than a drive strength of a fixed inverter element within the configurable delay circuit.

18. The method of claim 12, wherein different delays of the inverted input signal relative to the input signal vary linearly based on at least one of the first control signal and the second control signal.

19. A computing system, comprising:
a configurable delay circuit comprising:
a fixed inverter element configured to receive an input signal and generate an inverted input signal that is delayed by a first amount of time relative to the input signal; and
a tri-state inverter element that is coupled in parallel with the fixed inverter circuit element and is configured to receive the input signal and reduce the first amount of time that the inverted input signal is delayed relative to the input signal when at least one of a first control signal and second control signal is activated, wherein the tri-state inverter element comprises a pull-up transistor that is activated by the first control signal and a pull-down transistor that is activated by the second control signal.

20. The computing system of claim 19, wherein different delays of the inverted input signal relative to the input signal vary linearly based on at least one of the first control signal and the second control signal.
